(19) United States
(12) Patent Application Publication
(10) Pub. No.: US 2026/0047000 A1
(43) Pub. Date: Feb. 12, 2026

(54) HYBRID PCB WITH PLANAR ANTENNA

(71) Applicant: SIGNIFY HOLDING B.V., EINDHOVEN (NL)

(72) Inventor: HENRICUS MATHIJS MARIA CREEMERS, EINDHOVEN (NL)

(21) Appl. No.: 19/101,269

(22) PCT Filed: Aug. 4, 2023
(86) PCT No.: PCT/EP2023/071629

§ 371 Date: Feb. 5, 2025

(30) Foreign Application Priority Data
Aug. 9, 2022 (EP) 22189386.0

(51) Int. Cl. H05K 1/02; H05K 1/05; H05K 3/00; H05K 3/46

(52) U.S. Cl. CPC H05K 1/0243; H05K 1/0206; H05K 1/056; H05K 3/0061; H05K 3/4608; H05K 2201/09027; H05K 2201/10098

(57) ABSTRACT

A printed circuit board formed of at least two layers. A first layer is thermally conductive and a second layer is thermally insulating. Both layers provide structural support and/or mechanical rigidity to the printed circuit board. A planar antenna is provided on the second layer.

### FIELD OF THE INVENTION

The present invention relates to the field of printed circuit boards, particularly those that mount a planar antenna.

### BACKGROUND OF THE INVENTION

Printed circuit boards are a widely established and popular part of modern electronic devices. Generally, printed circuit boards provide structural support for electronic components of the electronic device, as well as defining electrical interconnects between electronic components coupled thereto.

It is common for an electronic device to comprise a plurality of printed circuit boards, e.g., each designed for a different function for the electronic device. As an example, a connected lighting arrangement may comprise a printed circuit board for each of the following functions: lighting; control; and radio/external communication.

There is an ongoing desire to reduce the size and/or number of printed circuit boards, in order to make electronic devices more compact.

### SUMMARY OF THE INVENTION

The invention is defined by the claims.

According to examples in accordance with an aspect of the invention, there is provided a printed circuit board comprising: a first layer, providing a core for the printed circuit board, formed of a thermally conductive material for spreading or dissipating heat and providing structural support for the printed circuit board; a second layer formed of an electrically insulating and mechanically rigid material, the second layer being at least partly mounted on top of the first layer and being suitable for supporting one or more electronic components desiring heat dissipation, wherein at least one electronic component mounted on the first portion dissipates heat via the first layer; and a planar antenna positioned on the second layer.

The present invention provides a printed circuit board for use in performing multiple functions, including external communication (via the planar antenna) and at least one other function (via the electronic components on the first portion of the second layer. This provides a more compact and space-efficient solution for electronic devices.

By providing the first (thermally conductive) layer, a heat sink/spreader is integrated into the printed circuit board for spreading or dissipating heat from the electronic components. For instance, the first layer may directly dissipate heat to an outside environment or spread/conduct heat to a (further) heat sink (e.g., a housing for the printed circuit board).

A mechanically rigid (but electrically insulating) material forms a second layer that is mounted on the first layer. The second layer provides a dual function of providing additional structural support to the printed circuit board, as well as electrically insulating electronic components from the first layer and/or, if present, any other layers between the first and second layer.

Approaches thereby provide a more compact printed circuit board, as multiple layers or elements perform dual functions in an efficient manner.

In some embodiments, the second layer comprises: a first portion, mounted on top of the first layer, for supporting the one or more electronic components desiring heat dissipation, wherein any electronic components mounted on the first portion dissipate heat through the first layer; and a second portion not mounted on top of the first layer; and the planar antenna is positioned on the second portion of the second layer.

It has been recognized that such a layer, particularly a thermally and/or electrically conductivity layer, in the vicinity of the antenna would affect the efficiency and/or sensitivity of the antenna. Based on the realization, it has been proposed to remove or not provide the first layer underneath the antenna.

This approach thereby improves the sensitivity and accuracy of the planar antenna, and thereby improves the operation of any PCB assembly comprising the disclosed printed circuit board.

Optionally, the second portion of the second layer is not completely surrounded by the first portion of the second layer. This approach improves the efficiency and/or sensitivity of the antenna, by reducing the amount of material surrounding the antenna to increase sensitivity to incoming/outgoing electromagnetic waves.

The first layer may be formed of a metal. This provides a mechanically robust core for the printed circuit board with good thermal conductivity. It has been recognized that, of commercially available and reliable materials, metals provide the most suitable characteristics for performing the dual function of heat spreading/dissipation and structural support. Suitable example metals include aluminum (preferred for weight), iron and/or steel.

The second layer is formed of an FR4 material. This provides a mechanically robust core for the printed circuit board with good insulation characteristics.

The planar antenna is preferably a meander antenna.

The printed circuit board may further comprise a first interconnect layer between the first layer and second layer, the first interconnect layer being formed of an electrically conductive material. The first interconnect layer may be appropriately patterned for connecting any relevant electronic components.

The printed circuit board may comprise an insulating layer between the first interconnect layer and the first layer, the insulating layer being formed of an electrically insulating material.

In some examples, the electrically insulating material is formed of a dielectric material.

Preferably, the thickness of the first layer is no less than 1 mm. For example, the thickness of the first layer is preferably no less than 2 mm, and more preferably no less than 5 mm. In some examples, the first layer is no less than 10 mm in thickness. Increasing the thickness of the first layer (e.g., to 1 mm or more) increases the structural support for the remainder of the printed circuit board.

The printed circuit board may comprise a second interconnect layer mounted on the second layer, such that at least part of the second layer is located between the second interconnect layer and the first layer, the second interconnect layer being formed of an electrically conductive material. The second interconnect layer may be appropriately patterned for connecting any relevant electronic components.

The second interconnect layer may provide a ground plane for the planar antenna.

The planar antenna may be a radiofrequency planar antenna, i.e., a planar antenna sized and shaped for providing and/or receiving radiofrequency communications.

There is also provided a printed circuit board (PCB) assembly, comprising the printed circuit board previously described and one or more electronic components mounted on the second layer. If the second layer is formed to have a first portion and a second portion, the one or more electronic components are preferably mounted on the second portion.

The one or more electronic components may, for instance, comprise control logic, radiofrequency communication processing equipment and so on. The one or more electronic components may, for instance, comprise one or more: resistors, inductors, capacitors, microprocessors, transistors, transformers, diodes and so on.

The printed circuit board assembly may further comprise a housing that houses the printed circuit board and the one or more electronic components. In some examples, the housing is thermally coupled to the first layer and is configured to thermally dissipate and/or spread heat away from the first layer. In some examples, the housing is formed of a thermally conductive material, such as metal.

There is also proposed a method of manufacturing a printed circuit board as herein disclosed. The method comprises: providing a first layer, providing a core for the printed circuit board, formed of a thermally conductive material for spreading or dissipating heat; providing a second layer, formed of an electrically insulating and mechanically rigid material, on top of the first layer; removing at least some of the first layer, to thereby define, in the second layer: a first portion, mounted on top of the first layer, for supporting one or more electronic components desiring heat dissipation; and a second portion not mounted on top of the first layer; and providing a planar antenna on the second portion of the second layer.

The method may further comprise providing a first interconnect layer on the first layer and second layer, the first interconnect layer being formed of an electrically conductive material, wherein the step of providing a second layer comprises providing the second layer on top of the first interconnect layer.

There is also proposed another method of manufacturing a printed circuit board as herein disclosed. The method comprises: providing a first layer, providing a core for the printed circuit board, formed of a thermally conductive material for spreading or dissipating heat; providing a first portion of a second layer, formed of an electrically insulating and mechanically rigid material, on top of the first layer; forming, separately to the first layer and the first portion of the second layer, a second portion of the second layer; coupling the second portion of the second layer to the first portion of the second layer, to thereby define a second layer comprising: the first portion, mounted on top of the first layer, for supporting one or more electronic components desiring heat dissipation; and the second portion not mounted on top of the first layer; and providing a planar antenna on the second portion of the second layer.

These and other aspects of the invention will be apparent from and elucidated with reference to the embodiment(s) described hereinafter.

### BRIEF DESCRIPTION OF THE DRAWINGS

For a better understanding of the invention, and to show more clearly how it may be carried into effect, reference will now be made, by way of example only, to the accompanying drawings, in which:

FIG. 1 provides a cross-sectional view of part of a printed circuit board;

FIG. 2 conceptually illustrates a printed circuit board;

FIG. 3 is a flowchart illustrating an approach for producing a printed circuit board; and

FIG. 4 is a flowchart illustrating another approach for producing a printed circuit board.

### DETAILED DESCRIPTION OF THE EMBODIMENTS

The invention will be described with reference to the Figures.

It should be understood that the detailed description and specific examples, while indicating exemplary embodiments of the apparatus, systems and methods, are intended for purposes of illustration only and are not intended to limit the scope of the invention. These and other features, aspects, and advantages of the apparatus, systems and methods of the present invention will become better understood from the following description, appended claims, and accompanying drawings. It should be understood that the Figures are merely schematic and are not drawn to scale. It should also be understood that the same reference numerals are used throughout the Figures to indicate the same or similar parts.

There is provided a printed circuit board formed of at least two layers. A first layer is thermally conductive and a second layer is thermally insulating. Both layers provide structural support and/or mechanical rigidity to the printed circuit board. A planar antenna is provided on the second layer.

Embodiments are based on the realization that a thermally-conductive core for a printed circuit board, whilst providing good heat spreading/dissipation, can affect the operation of an antenna and may not provide sufficient structural support. The present invention proposes to further provide an additional (second) layer of thermally insulating, but structurally rigid, material for mounting electronic components and a planar antenna.

Further embodiments additionally recognize that a conductive core in the vicinity of a planar antenna will affect its operation, e.g., reduce its sensitivity and/or accuracy. It is proposed to split the second layer into a first part located on the core and a second part not mounted on the core, so that the planar antenna is distanced from the core. The second layer provide sufficient structural support for the planar antenna.

Disclosed approaches can be employed in any suitable printed circuit board configuration that makes use of planar antennas, and find particular use in radiofrequency printed circuit board assemblies.

In the context of the present disclosure, if a layer is mounted “on top of” another layer, then the layers are structured such that one layer structurally supports the other layer. There may be additional layers located between layers for which one is mounted on top of the other.

In particular, a first hypothetical layer may be considered to be “on top of” a second hypothetical layer if, immediately after manufacture of a printed circuit board comprising the first and second hypothetical layers, the first hypothetical layer is vertically above the second hypothetical layer, e.g., so that a vertical hypothetical line (being a line parallel to a direction of gravity) would pass through the first and second hypothetical layers.

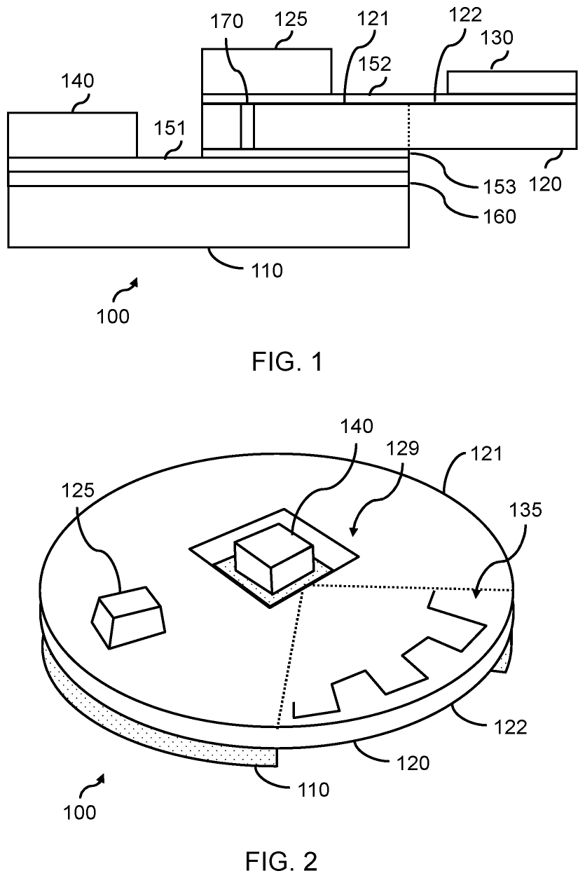

FIG. 1 conceptually provides a cross-sectional view of a printed circuit board 100 according to an embodiment. FIG. 1 is used to conceptually illustrate the proposed approach, and is merely schematic.

The printed circuit board comprises a first layer 110 that provides a core for the printed circuit board 100. The first layer 110 is formed of a thermally conductive material configured to spread or dissipate heat. The first layer also provides structural support for the printed circuit board.

Suitable example materials for performing the necessary functionality will be apparent to the skilled person, and include metals such as aluminum, iron or steel, as well as other material such as ceramics (e.g. aluminum oxide or alumina (Al₂O₃) or aluminum nitride). Preferably, the first layer is formed of a material having a thermal conductivity of no less than 20 Wm⁻¹K⁻¹ (e.g., at 20° C.) and a Young's modulus of no less than 50 GPa.

The first layer may be appropriately sized to achieve its desired function, e.g., of at least providing structural support for the printed circuit board. For instance, the first layer may have a thickness of no less than 1 mm. In some examples, the thickness of the first layer is preferably no less than 2 mm, and more preferably no less than 5 mm. In some examples, the first layer is no less than 10 mm in thickness. Increasing the thickness of the first layer (e.g., to 1 mm or more) increases the structural support for the remainder of the printed circuit board.

The first layer 110 thereby acts as both a structural support and a heat spreader/sink or heat spreader for the printed circuit board 100.

The printed circuit board 100 also comprises a second layer 120 that is at least partly mounted on top of the first layer. In the illustrated example, the second layer is only partly mounted on top of the first layer. The thickness of the second layer 120 may be 0.1 mm to 4 mm, e.g., 0.1 mm to 2 mm, e.g., 0.1 mm to 1 mm, e.g., 0.5 mm.

The second layer is formed of an electrically insulating and mechanically rigid material. Example materials include FR4 (or FR-4) materials or other similar materials having high dielectric constants or relative permittivities, such as ceramics.

The second layer is configured for supporting one or more electronic components desiring heat dissipation. At least one electronic component 125 mounted on the first portion dissipates heat via the first layer. Thus, the first layer may directly dissipate heat from the at least one electronic component 125 and/or spread/conduct heat to a/another heat sink for dissipation.

The second layer provides additional structural support for the printed circuit board, particularly components positioned thereon. The second layer also acts to electrically insulate electronic components from the first layer and/or, if present, any other layers between the first and second layer.

The printed circuit board 100 also comprises a planar antenna 130, which is a planar antenna positioned on the second layer. The planar antenna 130 may, for instance, be a meander antenna.

The planar antenna may be a radiofrequency planar antenna, i.e., a planar antenna sized and shaped for providing and/or receiving radiofrequency communications.

Thus, the planar antenna may be configured to generate electrical signals that change responsive to incoming radiofrequency waves and/or generate radiofrequency waves responsive to provided electrical signals. Approaches for configuring a planar antenna for such purposes are well known in the art.

Other forms of planar antenna (i.e., non-radiofrequency planar antenna) may also be employed in other embodiments of the invention.

FIG. 1 illustrates a particularly advantageous version of the printed circuit board. In this version, the second layer is conceptually divisible into a first portion 121 and a second portion 122. This division is conceptually represented with a dotted line.

The first portion 121 is mounted on top of the first layer and is configured to support the one or more electronic components 125 desiring heat dissipation. As before, any electronic components mounted on the first portion dissipate heat through the first layer.

The second portion 122 is not mounted on top of the first layer. Rather, it is structurally supported by the first layer 110 via the first portion 121. Thus, the second portion 122 is structurally supported by the first portion 121 of the second layer.

The planar antenna 130 is positioned on the second portion 122 of the second layer. The material of the second layer 120 provides the mechanical stiffness for supporting the antenna in the second portion 122 of the second layer. In particular, the second portion 122 of the second layer provide mechanical stability for the planar antenna 130.

In this way, a region of the first layer 110 is absent in the vicinity of the planar antenna and the second portion 122 of the second layer. Thus, the first layer does not provide direct structural support for the second portion 122 of the second layer 120 or the planar antenna 130 (rather, only providing support via the first portion 121 of the second layer).

Preferably, the second portion 122 of the second layer 120 is not completely surrounded by the first portion of the second layer. Thus, the second portion 122 can effectively overhang the first layer 110. This approach reduces the amount of material in the vicinity of the antenna, which can increase the sensitivity of the antenna to electromagnetic radiation.

It will be appreciated that the printed circuit board 100 may comprise the one or more electronic components 125 desiring heat dissipation, to form a printed circuit board assembly. However, this is not essential, and the printed circuit board 100 may instead comprise locations or zones to which one or more electronic components 125 can be subsequently coupled or connected, as is well known in the art.

Although only one electronic component 125 is illustrated in FIG. 1, this is purely schematic for the sake of understanding. In practice, the printed circuit board may be configured to mount any number of electronic components, e.g., more than 10 components or more than 100 components.

Other optional features of the printed circuit board 100 are also illustrated in FIG. 1.

Some electronic components, such as an LED, generate a substantive amount of heat. Thus, it would be preferable to thermally couple such components more closely with the first layer 110 (which acts as a heat spreader/sink).

Thus, in some examples, one or more additional electrical components 140 may be mounted on the first layer 110, but not the second layer 120. Thus, one or more electrical components may be directly structurally supported by the first layer 110, but not the second layer 120 (i.e., when the first layer rests on a flat surface).

This more closely thermally couples the one or more additional electrical components to the first layer, improving the heat dissipation of such components with respect to the printed circuit board.

As before, it will be appreciated that the printed circuit board 100 may comprise the one or more additional electronic components 140. However, this is not essential, and the printed circuit board 100 may instead comprise locations or zones to which one or more additional electronic components 140 can be subsequently coupled or connected, as is well known in the art.

Although only one additional electronic component 140 is illustrated in FIG. 1, this is purely schematic for the sake of understanding. In practice, the printed circuit board may be configured to mount any number of additional electronic components, e.g., more than 10 additional components or more than 100 additional components.

It is commonly desirable to provide interconnects on a printed circuit board 100, to connect components supported thereon for performing a desired function. The printed circuit board may thereby comprise one or more interconnect layers 151, 152, 153 formed of an electrically conductive material.

For instance, the printed circuit board may comprise a first interconnect layer 151 between the first layer 110 and the second layer 120. The first interconnect layer 151 may, for instance, provide electrical connection to any additional electronic component(s) 140 mounted on the first layer 110 (but not the second layer 120). The first interconnect layer 151 is formed of an electrically conductive material.

The printed circuit board 100 may comprise a second interconnect layer 152 mounted on the second layer 120. In particular, the second interconnect layer is positioned such that at least part of the second layer is located between the second interconnect layer and the first layer. The second interconnect layer 152 is also formed of an electrically conductive material.

The second interconnect layer may also provide a ground plane for the planar antenna.

It will be appreciated that the second interconnect layer 152 does not need to be located beneath the planar antenna 130 as illustrated in FIG. 1. Rather, the second interconnect layer 152 and the planar antenna 130 may be both (directly) mounted on the second layer 120. In particular, the planar antenna 130 may effectively form part of the second interconnect layer 130 and/or the second interconnect layer may provide electrical connections for the planar antenna 130.

The printed circuit board 100 may comprise a third interconnect layer 153 mounted between the first interconnect layer 151 and the second layer 120. The third interconnect layer 152 allows for increased ease of assembly or manufacturing of the printed circuit board (e.g., to allow separate production of the first and second layers, before being coupled together via the first and second interconnect layers). The third interconnect layer 153 is also formed of an electrically conductive material.

Example electrically conductive materials for use as the material of the first, second and/or third interconnect layer (where relevant) include copper, gold or silver. Copper is usually preferred due to its low cost and ease of manufacture (e.g., to perform soldering or the like).

Each interconnect layer 151, 152, 153 (if/when present) may be structured in the form of one or more electrical traces, e.g., for connecting locations to which electronic components are or are to be coupled. The electrical traces may form a predetermined connection pattern for achieving a desired communication goal. Approaches for forming such traces are well known in the art of printed circuit boards.

To prevent components from providing an electrical current to the first layer 110 (which acts as a heat spreader/sink), the printed circuit board may further comprise an insulating layer 160 between the first interconnect layer 151 and the first layer 110. The insulating layer may have a thickness of between 0.05 mm to 1 mm, e.g., 0.1 mm.

The insulating layer is formed of an electrically insulating material, such as a dielectric material (e.g., aluminum nitride or silicon carbide). Preferably, the insulating material has a thermal conductivity of no less than 20 Wm⁻¹K⁻¹ (e.g., at 20° C.) for improved heat dissipation.

Use of an insulating layer is particularly advantageous when the first layer is formed of an electrically conductive material, such as metal (e.g., aluminum). This prevents the first layer from becoming electrically charged, and potentially dangerous to a subject that (e.g., unintentionally) touches the first layer.

The printed circuit board 100 may further comprise one or more vias 170 or interconnects through the second layer 120. This allows components mounted on the second layer 120 to electrically communicate with any components not mounted on the first layer through the via(s) and the first/second interconnect layers.

Each via(s) is a hole through the second layer 120 that is filled or coated with an electrically conductive material, such as a metal (e.g., copper, gold or silver).

The via(s) also act to provide heat dissipation for components mounted on the second layer, e.g., by conducting heat through the via to the first layer 110. This approach is particularly advantageous when the second layer is thermally insulating, e.g., is formed of a FR4 material or the like.

Each via may comprise a plug of thermally conductive material, e.g., completely or partially filling the via, for improved thermal dissipation. Example thermally conductive materials include metal, as well as some ceramics. In some examples, each via is a hole coated with a metal (for providing the electrical connection) and filled with a plug of thermally conductive material such as a ceramic.

Although only one via is illustrated, the printed circuit board may comprise any number of vias, as would be readily apparent to the skilled person.

FIG. 2 provides a perspective view of an example printed circuit board 100. For the sake of clarity, only two electronic components have been illustrated, but the skilled person would readily appreciate that, in practice, such a printed circuit board 100 may be configured to mount any number of electronic components.

FIG. 2 more clearly illustrates how the planar antenna 130 may be mounted on a second portion 122 of the second layer 120, which is not mounted on (e.g., directly structurally supported) by the first layer 110.

This Figure also more clearly demonstrates how an additional electronic component 140 can be mounted to the first layer 110 without being mounted on the second layer 120. In particular, the second layer 120 may comprise one or more cavities 129, into which any such additional electronic components may be positioned.

Other layers, such as the interconnect layer(s) and/or the insulating layer have not been directly illustrated in FIG. 2 for the sake of illustrative clarity. In particular, FIG. 2 is useful for understanding the spatial relationship between the first and second layers.

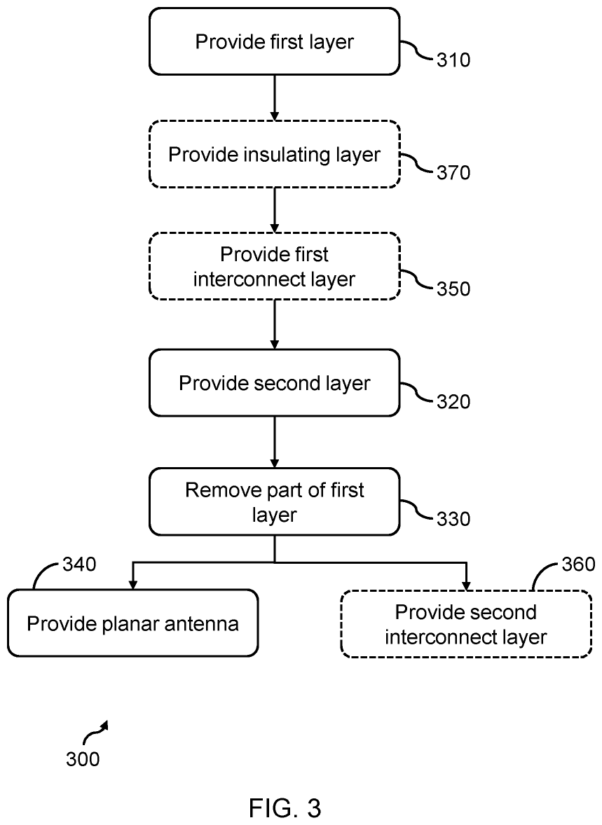

FIG. 3 is a flowchart illustrating a method 300 for manufacturing a printed circuit board, as herein disclosed.

The method 300 comprises a step 310 of providing a first layer, providing a core for the printed circuit board, formed of a thermally conductive material for spreading or dissipating heat. Step 310 may, for instance, be performed using a deposition technique or a cutting/dicing technique.

The method 300 also comprises a step 320 of providing a second layer, formed of an electrically insulating and mechanically rigid material, on top of the first layer. Step 320 may be performed, for instance, by depositing the second layer on top of the first layer. As another example, step 320 can be performed by separately producing the second layer, and bonding or otherwise mounting the second layer to the first layer.

As an alternative example, steps 310 and 320 may be performed by depositing the first layer on the second layer, or by mounting or bonding separately produced first and second layers together.

After performing steps 310 and 320, the first and second layers may have a same cross-sectional area (e.g., when viewed from above).

The method also comprises a step 330 of removing at least some of the first layer. This thereby defines, in the second layer: a first portion, mounted on top of the first layer, for supporting one or more electronic components desiring heat dissipation; and a second portion not mounted on top of the first layer.

The method 300 also comprises a step 340 of providing a planar antenna on the second portion of the second layer. Approaches for performing this step would be readily apparent to the skilled person, and may include using a deposition or printing technique, which may be followed by an etching step if required, to form the planar antenna. Of course, some deposition techniques would not require an etching step to produce the shape or form of the planar antenna.

Steps 330 and 340 can be performed in reverse order, so that removal of at least some of the first layer takes place after the planar antenna has been provided on the second portion of the second layer.

Of course, method 300 may be appropriately modified to include the provision of other optional layers of the printed circuit board.

For instance, the method 300 may further comprise a step 350 of providing a first interconnect layer between the first layer and second layer, the first interconnect layer being formed of an electrically conductive material. Accordingly, step 320 may be modified to comprise providing a second layer on top of the first interconnect layer.

Similarly, the method 300 may further comprise a step 360 of providing a second interconnect layer on the second layer (so that the second layer is positioned between the first layer and the second interconnect layer). This can be performed after performing step 320, any/or may be integrated into the performance of step 340. Thus, the planar antenna and the second interconnect layer may be produced or provided simultaneously or in a same process (e.g., a same deposition and optional etching process).

The method 300 may further comprise a step 370 of providing an insulating layer between the first interconnect layer and the first layer. This can, for instance, be performed using a deposition technique. Of course, when step 370 is performed, the first interconnect layer may not yet exist.

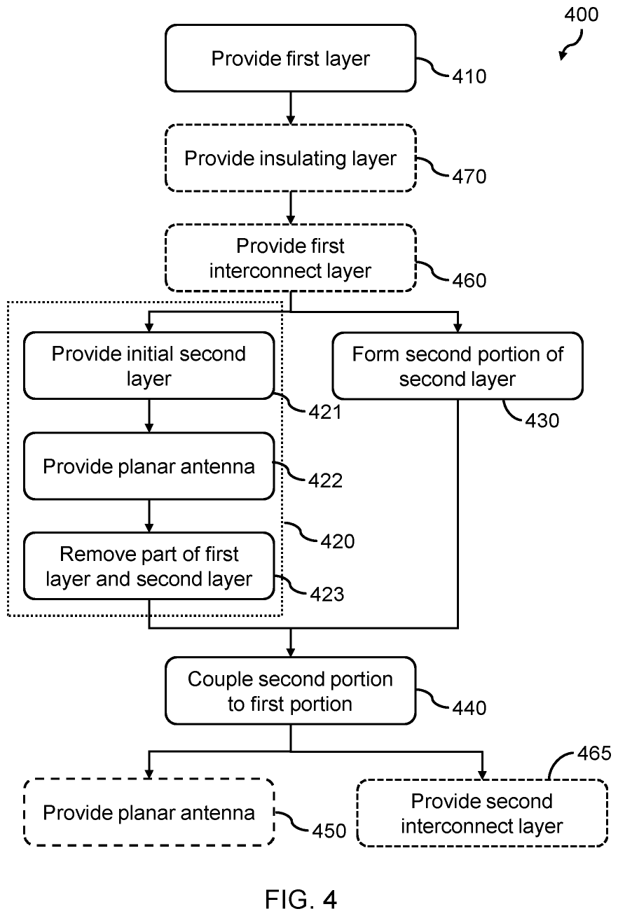

FIG. 4 is a flowchart illustrating an alternative method 400 for manufacturing a printed circuit board, as herein disclosed.

The method 400 comprises a step 410 of providing of a first layer, providing a core for the printed circuit board, formed of a thermally conductive material for spreading or dissipating heat.

The method 400 further comprises a step 420 of providing a first portion of a second layer, formed of an electrically insulating and mechanically rigid material, on top of the first layer. The portion of the second layer provided on the first layer in this way can act as the first portion.

Steps 410 and 420 may be performed in an analogous manner to any previously described step 310, 320 (with reference to FIG. 3).

The method 400 further comprises a step 430 of forming, separately to the first layer and the first portion of the second layer, a second portion of the second layer.

The method then performs a step 440 of coupling the second portion of the second layer to the first portion of the second layer. This can be performed using any suitable bonding technique.

Performance of step 440 thereby defines a second layer comprising the first portion, mounted on top of the first layer, for supporting one or more electronic components desiring heat dissipation; and the second portion not mounted on top of the first layer.

The method 400 also comprises a step 450 of providing a planar antenna on the second portion of the second layer. This can be performed in any approach analogous to previously described step 340. Step 450 can be performed before or after step 440.

In one variation to method 400, step 450 is performed as part of steps 420 and 440. In this approach, step 420 comprises: a step 421 of providing an initial second layer on top of the first layer; a step 422 of providing a planar antenna on the second layer and a step 423 of etching or removing parts of the first and second layer in the vicinity of the planar antenna. The remaining (non-removed) part of the second layer forms the first portion of the second layer. The second portion (generated in step 430) is then coupled to the first portion to perform both steps 440 and steps 450.

Like previously described method 300, method 400 may be appropriately modified to include the provision of other optional layers of the printed circuit board.

For instance, the method 400 may further comprise a step 460 of providing a first interconnect layer between the first layer and second layer, the first interconnect layer being formed of an electrically conductive material. Accordingly, step 420 may be modified to comprise providing a second layer on top of the first interconnect layer.

Similarly, the method 400 may further comprise a step 465 of providing a second interconnect layer on the second layer (so that the second layer is positioned between the first layer and the second interconnect layer). This can be performed after performing step 420, any/or may be integrated into the performance of step 450, where appropriate. Thus, the planar antenna and the second interconnect layer may be produced or provided simultaneous or in a same process (e.g., a same deposition and optional etching process).

The method 400 may further comprise a step 470 of providing an insulating layer between the first interconnect layer and the first layer. This can, for instance, be performed using a deposition technique. Of course, when step 470 is performed, the first interconnect layer may not yet exist.

Other variations and modifications to the herein described methods for manufacturing the printed circuit board will be apparent to the skilled person.

Suitable deposition techniques for use in proposed embodiments are well known in the art of circuit manufacture, and are not described here for the sake of clarity.

Example deposition techniques include physical or chemical vapor deposition techniques, sputtering techniques and the like.

Variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a”or “an”does not exclude a plurality.

The mere fact that certain measures are recited in mutually different dependent claims does not indicate that a combination of these measures cannot be used to advantage.

If the term “adapted to” is used in the claims or description, it is noted the term “adapted to” is intended to be equivalent to the term “configured to”. If the term “arrangement” is used in the claims or description, it is noted the term “arrangement” is intended to be equivalent to the term “system”, and vice versa.

Any reference signs in the claims should not be construed as limiting the scope.

1. A printed circuit board comprising:
a first layer, providing a core for the printed circuit board, formed of a thermally conductive material for spreading or dissipating heat and providing structural support for the printed circuit board;
a second layer comprising:
a first portion, mounted on top of the first layer, for supporting the one or more electronic components desiring heat dissipation, wherein any electronic components mounted on the first portion dissipate heat through the first layer;
a second portion not mounted on top of the first layer,
wherein the second layer is formed of an electrically insulating and mechanically rigid material, the second layer being at least partly mounted on top of the first layer and being suitable for supporting one or more electronic components desiring heat dissipation, wherein at least one electronic component mounted on the first portion dissipates heat via the first layer; and
a planar antenna positioned on the second portion of the second layer.

2. (canceled)

3. The printed circuit board of claim 1, wherein the first layer is formed of a metal.

4. The printed circuit board of claim 1, wherein the second layer is formed of an FR4 material.

5. The printed circuit board of claim 1, wherein the planar antenna is a meander antenna.

6. The printed circuit board of claim 1, further comprising a first interconnect layer between the first layer and second layer, the first interconnect layer being formed of an electrically conductive material.

7. The printed circuit board of claim 6, further comprising an insulating layer between the first interconnect layer and the first layer, the insulating layer being formed of an electrically insulating material.

8. The printed circuit board of claim 7, wherein the electrically insulating material is formed of a dielectric material.

9. The printed circuit board of claim 1, wherein the thickness of the first layer is no less than 1 mm.

10. The printed circuit board of claim 6, further comprising a second interconnect layer mounted on the second layer, such that at least part of the second layer is located between the second interconnect layer and the first layer, the second interconnect layer being formed of an electrically conductive material.

11. The printed circuit board of claim 10, wherein the second interconnect layer provides a ground plane for the planar antenna.

12. A method of manufacturing a printed circuit board, the method comprising:
providing a first layer, providing a core for the printed circuit board, formed of a thermally conductive material for spreading or dissipating heat and providing structural support for the printed circuit board;
providing a second layer, formed of an electrically insulating and mechanically rigid material, on top of the first layer;
removing at least some of the first layer, to thereby define, in the second layer:
a first portion, mounted on top of the first layer, for supporting one or more electronic components desiring heat dissipation, wherein any electronic components mounted on the first portion dissipate heat through the first layer; and
a second portion not mounted on top of the first layer, wherein the second layer is formed of an electrically insulating and mechanically rigid material, the second layer being at least partly mounted on top of the first layer and being suitable for supporting one or more electronic components desiring heat dissipation, wherein at least one electronic component mounted on the first portion dissipates heat via the first layer; and
providing a planar antenna on the second portion of the second layer.

13. The method of claim 12, further comprising providing a first interconnect layer on the first layer and second layer, the first interconnect layer being formed of an electrically conductive material, wherein
the step of providing a second layer comprises providing the second layer on top of the first interconnect layer.

14. A method of manufacturing a printed circuit board, the method comprising:
providing a first layer, providing a core for the printed circuit board, formed of a thermally conductive material for spreading or dissipating heat and providing structural support for the printed circuit board;
providing a first portion of a second layer, formed of an electrically insulating and mechanically rigid material, on top of the first layer, wherein any electronic components mounted on the first portion dissipate heat through the first layer;
forming, separately to the first layer and the first portion of the second layer, a second portion of the second layer, wherein the second layer is formed of an electrically insulating and mechanically rigid material;
coupling the second portion of the second layer to the first portion of the second layer, to thereby define a second layer comprising:
the first portion, mounted on top of the first layer, for supporting one or more electronic components desiring heat dissipation; and
the second portion not mounted on top of the first layer; and
providing a planar antenna on the second portion of the second layer.
